(19) United States
(12) Patent Application Publication
(10) Pub. No.: US 2024/0321789 A1
(43) Pub. Date: Sep. 26, 2024

(54) BONDING-TYPE INTERCONNECTION MEMBER

(71) Applicants: Kabushiki Kaisha Toshiba, Tokyo (JP); Toshiba Electronic Devices & Storage Corporation, Tokyo (JP)

(72) Inventors: Kazuyuki HIGASHI, Yokohama Kanagawa (JP); Kei OBARA, Kawasaki Kanagawa (JP); Kazumichi TSUMURA, Shinagawa Tokyo (JP)

(21) Appl. No.: 18/458,109

(22) Filed: Aug. 29, 2023

(30) Foreign Application Priority Data
Mar. 22, 2023 (JP) 2023-045023

(51) Int. Cl. H01L 23/00; H01L 25/065

(52) U.S. Cl. CPC H01L 24/05; H01L 24/13; H01L 25/0657; H01L 2224/0401; H01L 2224/05011; H01L 2224/05082; H01L 2224/05166; H01L 2224/05551; H01L 2224/05573; H01L 2224/05664; H01L 2224/05666; H01L 2224/13019; H01L 2224/13022; H01L 2224/13026; H01L 2224/13144; H01L 2225/06513

(57) ABSTRACT

A bonding-type interconnection member includes a first substrate; a first interconnection portion stacked on the first substrate and including a first insulating layer, a first interconnection layer, and a first connection hole reaching the first interconnection layer; a second substrate facing the first interconnection portion in a first direction; a bonding metal portion provided between the first connection hole and the second substrate; a first conductive film provided in the first connection hole and in contact with the first interconnection layer on a bottom surface of the first connection hole; and a second conductive film provided between the first conductive film and the bonding metal portion, and in contact with the first conductive film and the bonding metal portion. The first conductive film is made of a material different from a material of the second conductive film and a material of the bonding metal portion.

### CROSS-REFERENCE TO RELATED APPLICATION

This application is based upon and claims the benefit of priority from Japanese Patent Application No. 2023-045023, filed on Mar. 22, 2023; the entire contents of which are incorporated herein by reference.

### FIELD

Embodiments described herein relate generally to a bonding-type interconnection member.

### BACKGROUND

A structure is known in which two chips are bonded by bonding metals.

### BRIEF DESCRIPTION OF THE DRAWINGS

FIG. 1 is a schematic cross-sectional view of a bonding-type interconnection member according to a first embodiment;

FIG. 2 to FIG. 7 are schematic cross-sectional views showing a method for manufacturing the bonding-type interconnection member according to the first embodiment;

FIG. 8 is a schematic cross-sectional view of a bonding-type interconnection member according to a second embodiment;

FIG. 9 is a schematic cross-sectional view of a bonding-type interconnection member according to a third embodiment; and

FIG. 10 is a schematic plan view showing an arrangement example of a first conductive film in the embodiments.

### DETAILED DESCRIPTION

According to one embodiment, a bonding-type interconnection member includes a first substrate; a first interconnection portion stacked on the first substrate and including a first insulating layer, a first interconnection layer provided in the first insulating layer, and a first connection hole reaching the first interconnection layer from a surface of the first insulating layer; a second substrate facing the first interconnection portion in a first direction; a bonding metal portion provided between the first connection hole and the second substrate in the first direction; a first conductive film provided in the first connection hole and in contact with the first interconnection layer on a bottom surface of the first connection hole; and a second conductive film provided between the first conductive film and the bonding metal portion, and in contact with the first conductive film and the bonding metal portion, the first conductive film being made of a material different from a material of the second conductive film and a material of the bonding metal portion.

Hereinafter, embodiments will be described with reference to the drawings.

The drawings are schematic or conceptual. A relationship between a thickness and a width of each portion, a ratio of sizes between portions, and the like are not necessarily the same as the actual ones. Even if the same portions are shown, dimensions and ratios may be shown differently from each other in the drawings.

Same components are denoted by same reference numerals.

### First Embodiment

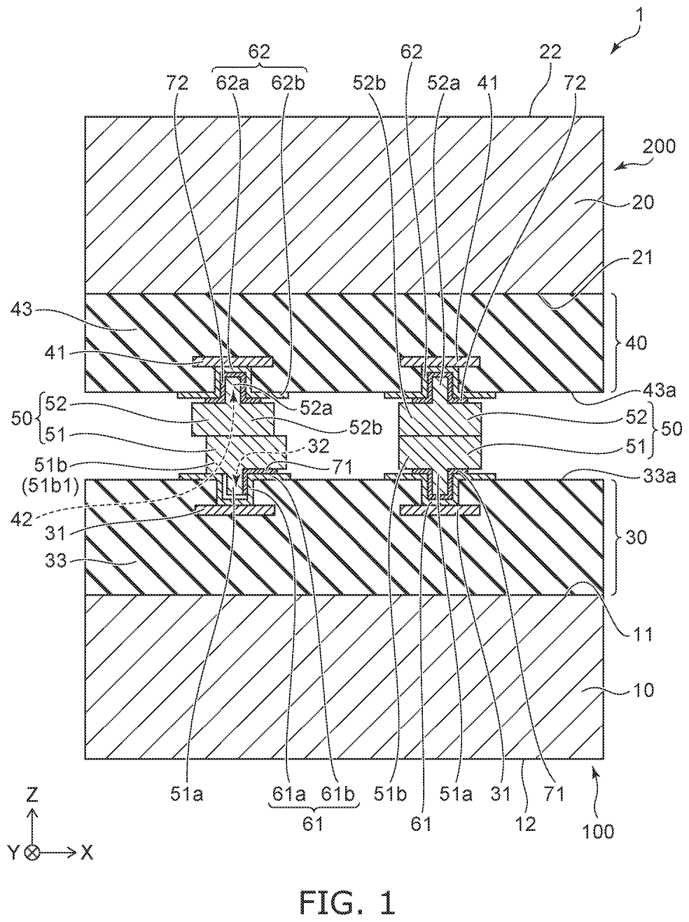

As shown in FIG. 1, a bonding-type interconnection member 1 according to a first embodiment includes a first chip 100 and a second chip 200. The first chip 100 and the second chip 200 are bonded via bonding metal portions 50, and are stacked in a first direction Z. Two directions orthogonal to the first direction Z are referred to as a second direction X and a third direction Y. The second direction X and the third direction Y are orthogonal to each other.

The first chip 100 includes a first substrate 10. The first substrate 10 has a first surface 11 and a second surface 12 located on an opposite-side surface from the first surface 11 in the first direction Z. The first substrate 10 is, for example, a silicon substrate.

The second chip 200 includes a second substrate 20. The second substrate 20 has a third surface 21 facing the first surface 11 of the first substrate 10 in the first direction Z, and a fourth surface 22 located on an opposite-side surface from the third surface 21 in the first direction Z. The second substrate 20 is, for example, a silicon substrate.

The first chip 100 includes a first interconnection portion 30 stacked on the first substrate 10. The first interconnection portion 30 is provided on the first surface 11 of the first substrate 10. In the first direction Z, the first interconnection portion 30 is located between the first substrate 10 and the second substrate 20. The first interconnection portion 30 includes a first insulating layer 33 and first interconnection layers 31 provided in the first insulating layer 33. The first interconnection layer 31 is made of, for example, a material mainly containing copper. Although FIG. 1 shows one first interconnection layer 31, the first interconnection portion 30 may include a plurality of first interconnection layers 31.

The first insulating layer 33 has a surface 33a facing the second substrate 20 in the first direction Z. The first interconnection portion 30 has first connection holes 32 reaching the first interconnection layers 31 from the surface 33a of the first insulating layer 33. The first connection hole 32 has an opening on a surface 33a side of the first insulating layer 33 and a bottom surface on a first interconnection layer 31 side. The first interconnection portion 30 has, for example, a plurality of the first connection holes 32. A plurality of the bonding metal portions 50 are arranged in at least one of the second direction X and the third direction Y corresponding to positions of the plurality of first connection holes 32. The bonding metal portion 50 is provided between the first connection hole 32 and the second substrate 20 in the first direction Z.

The first chip 100 further includes first conductive films 61 provided in the first connection holes 32 and in contact with the first interconnection layers 31 on the bottom surfaces of the first connection holes 32. The first conductive film 61 is provided to be continuous with the surface 33a of the first insulating layer 33 and a side surface and the bottom surface of the first connection hole 32. The first conductive film 61 includes a first portion 61a located in the first connection hole 32 and a second portion 61b located on the surface 33a of the first insulating layer 33.

The first chip 100 further includes second conductive films 71 provided between the first conductive films 61 and the bonding metal portions 50 and in contact with the first conductive films 61 and the bonding metal portions 50. A plurality of the second conductive films 71 are separated from each other and provided under the plurality of bonding metal portions 50.

The bonding metal portion 50 is electrically connected to the first interconnection layer 31 via the first conductive film 61 and the second conductive film 71. The bonding metal portion 50 includes a first metal portion 51a located in the first connection hole 32 and a second metal portion 51b facing the second portion 61b of the first conductive film 61.

The second conductive film 71 is in contact with the first conductive film 61 and the bonding metal portion 50 between the second metal portion 51b of the bonding metal portion 50 and the second portion 61b of the first conductive film 61. The second conductive film 71 is in contact with the first conductive film 61 and the bonding metal portion 50 between side surfaces of the first metal portion 51a of the bonding metal portion 50 and the first portion 61a of the first conductive film 61.

In FIG. 1, for example, the bonding metal portion 50 located on a left side includes a portion where the second metal portion 51b and the second portion 61b of the first conductive film 61 are in direct contact with each other without the second conductive film 71 interposed between the second metal portion 51b and the second portion 61b.

The first conductive film 61 is made of a material different from a material of the second conductive film 71 and a material of the bonding metal portion 50. Here, the material represents a material mainly constituting each member. For example, the bonding metal portion 50 mainly contains gold, the first conductive film 61 mainly contains titanium nitride, and the second conductive film 71 mainly contains palladium or titanium. The second conductive film 71 may be a stacked film of a palladium film and a titanium film.

As described later, the second conductive film 71 functions as a seed layer when the bonding metal portion 50 is formed by a plating method, and after the bonding metal portion 50 is precipitated, a process of removing an unnecessary portion of the second conductive film 71 on the surface 33a of the first insulating layer 33 is performed. For example, when misalignment occurs between the bonding metal portion 50 and the first connection hole 32 located on the left side in FIG. 1, an etchant may enter the first connection hole 32 and a part of the second conductive film 71 in the first connection hole 32 may disappear. In this case, a gap is formed between the first interconnection layer 31 and the first metal portion 51a of the bonding metal portion 50 in the first connection hole 32, and a conduction failure or an increase in contact resistance between the first interconnection layer 31 and the bonding metal portion 50 may occur.

According to the embodiment, by previously forming the first conductive film 61 in contact with the first interconnection layer 31 in the first connection hole 32 with a material different from that of the second conductive film 71, the first conductive film 61 in contact with the first interconnection layer 31 can reliably remain in the first connection hole 32 even after an etching process of the second conductive film 71. Accordingly, the first interconnection layer 31 can be electrically connected to the bonding metal portion 50 via the first conductive film 61. As a result, reliability of the bonding-type interconnection member 1 can be improved.

According to the embodiment, as shown in the bonding metal portion 50 located on the left side in FIG. 1, the bonding metal portion 50 includes a portion where the second metal portion 51b is connected to the first conductive film 61 via the second conductive film 71, and a portion 51b1 where the second metal portion 51b is in direct contact with the first conductive film 61 without the second conductive film 71 interposed between the second metal portion 51b and the first conductive film 61. Therefore, adhesion between the bonding metal portion 50 and the first conductive film 61 can be improved, and peeling due to stress of the film itself or thermal stress in subsequent processes can be prevented.

The second chip 200 may have the same configuration as the first chip 100. For example, the second chip 200 includes a second interconnection portion 40 stacked on the second substrate 20. The second interconnection portion 40 is provided on the third surface 21 of the second substrate 20. The second interconnection portion 40 is located between the first interconnection portion 30 and the second substrate 20 in the first direction Z. The second interconnection portion 40 includes a second insulating layer 43 and second interconnection layers 41 provided in the second insulating layer 43. The second interconnection layer 41 is made of, for example, a material mainly containing copper. Although FIG. 1 shows one second interconnection layer 41, the second interconnection portion 40 may include a plurality of the second interconnection layers 41.

The second insulating layer 43 has a surface 43a facing the first interconnection portion 30 in the first direction Z. The second interconnection portion 40 has second connection holes 42 reaching the second interconnection layers 41 from the surface 43a of the second insulating layer 43. The second connection hole 42 has an opening on a surface 43a side of the second insulating layer 43 and a bottom surface on a second interconnection layer 41 side. The second interconnection portion 40 has, for example, a plurality of the second connection holes 42 corresponding to positions of the plurality of bonding metal portions 50. The bonding metal portion 50 is provided between the first connection hole 32 and the second connection hole 42 in the first direction Z.

The second chip 200 further includes third conductive films 62 provided in the second connection holes 42 and in contact with the second interconnection layers 41 on the bottom surfaces of the second connection holes 42. The third conductive film 62 is provided to be continuous with the surface 43a of the second insulating layer 43 and a side surface and the bottom surface of the second connection hole 42. The third conductive film 62 includes a third portion 62a located in the second connection hole 42 and a fourth portion 62b located on the surface 43a of the second insulating layer 43.

The second chip 200 further includes fourth conductive films 72 provided between the third conductive films 62 and the bonding metal portions 50 and in contact with the third conductive films 62 and the bonding metal portions 50. A plurality of the fourth conductive films 72 are separated from each other and provided on the plurality of bonding metal portions 50.

The bonding metal portion 50 is electrically connected to the second interconnection layer 41 via the third conductive film 62 and the fourth conductive film 72. The bonding metal portion 50 includes a third metal portion 52a located in the second connection hole 42 and a fourth metal portion 52b facing the fourth portion 62b of the third conductive film 62.

The fourth conductive film 72 is in contact with the third conductive film 62 and the bonding metal portion 50 between the fourth metal portion 52b of the bonding metal portion 50 and the fourth portion 62b of the third conductive film 62. The fourth conductive film 72 is in contact with the third conductive film 62 and the bonding metal portion 50 between side surfaces of the third metal portion 52a of the bonding metal portion 50 and the third portion 62a of the third conductive film 62.

The first interconnection layer 31 of the first chip 100 is electrically connected to the second interconnection layer 41 of the second chip 200 via the first conductive film 61, the second conductive film 71, the bonding metal portion 50, the fourth conductive film 72, and the third conductive film 62.

As will be described later, one bonding metal portion 50 is formed by integrating a first bonding metal portion 51 provided on a first chip 100 side and a second bonding metal portion 52 provided on a second chip 200 side by metal diffusion bonding by applying heat and a force.

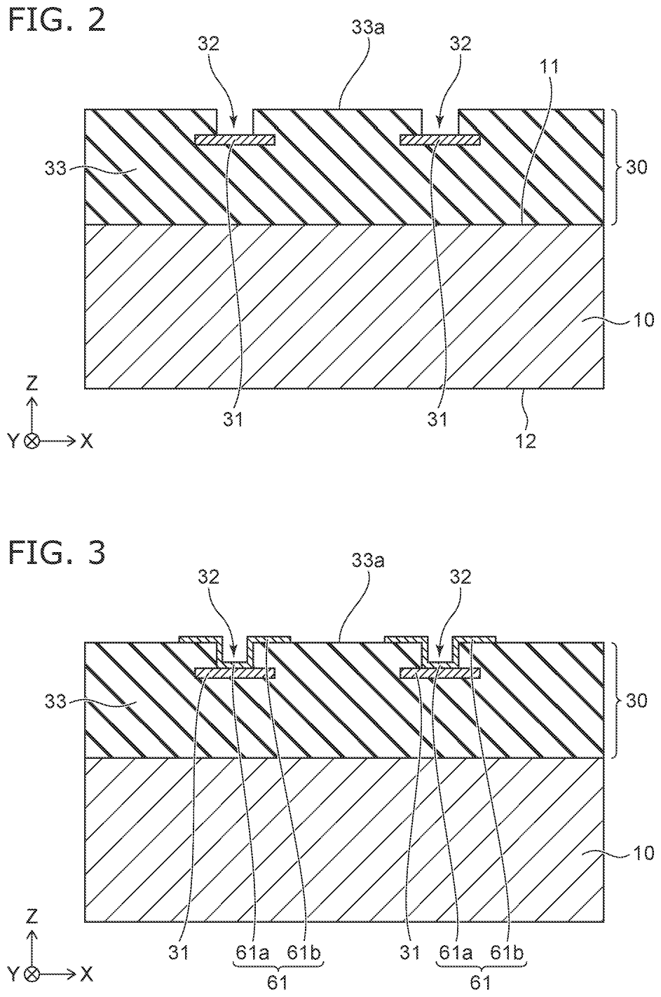

Next, a manufacturing method of the bonding-type interconnection member 1 according to the first embodiment will be described with reference to FIGS. 2 to 7.

As shown in FIG. 2, the first interconnection portion 30 is formed on the first surface 11 of the first substrate 10. The first interconnection portion 30 is formed with the first connection holes 32 reaching the first interconnection layers 31 from the surface 33a of the first insulating layer 33. The first connection hole 32 can be formed by, for example, a reactive ion etching (RIE) method. The first connection hole 32 is a bottomed hole having an opening in the surface 33a of the first insulating layer 33.

After the first connection hole 32 is formed, as shown in FIG. 3, the first conductive film 61 is formed in the first connection hole 32. The first conductive film 61 can be formed, for example, by forming a film mainly containing titanium nitride by a sputtering method and then by an RIE method using a resist mask patterned by lithography. The first conductive film 61 includes the first portion 61a provided on the side surface and the bottom surface of the first connection hole 32, and the second portion 61b provided on the surface 33a of the first insulating layer 33 around the first connection hole 32.

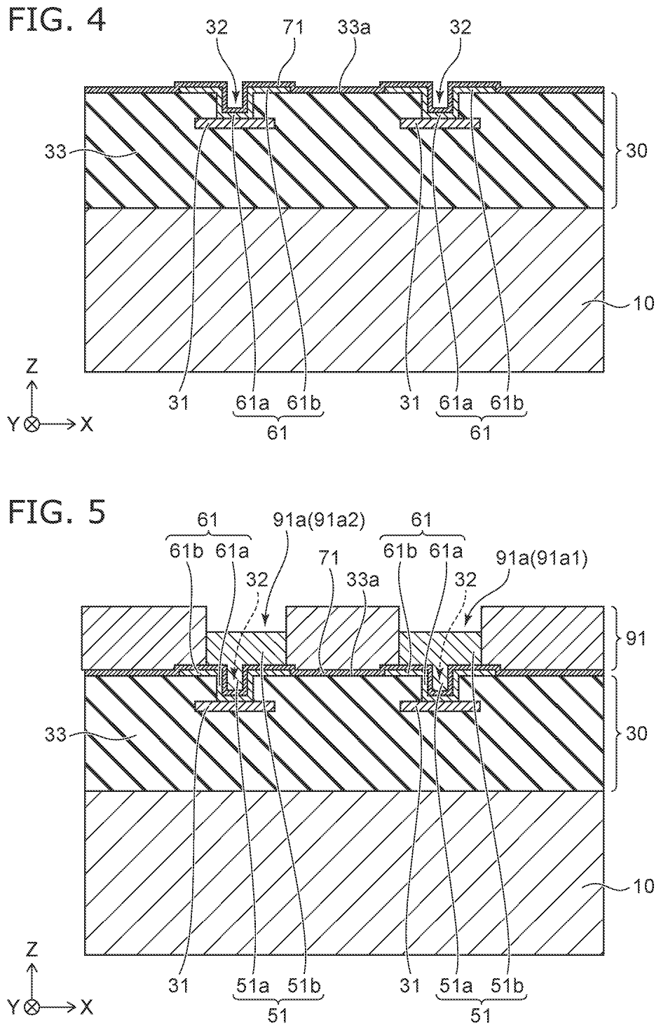

After the first conductive film 61 is formed, as shown in FIG. 4, the second conductive film 71 is formed in the first connection hole 32 and on the surface 33a of the first insulating layer 33. The second conductive film 71 can be formed as, for example, a film mainly containing palladium or titanium by a sputtering method. The second conductive film 71 continuously covers the first portion 61a of the first conductive film 61 in the first connection hole 32, the second portion 61b of the first conductive film 61 on the surface 33a of the first insulating layer 33, and the surface 33a of the first insulating layer 33. The second conductive film 71 is in contact with the first portion 61a and the second portion 61b of the first conductive film 61.

After the second conductive film 71 is formed, the first bonding metal portion 51 is formed. As shown in FIG. 5, the first bonding metal portion 51 is formed as a metal film mainly containing gold by a plating method using a resist mask 91. The second conductive film 71 functions as a seed layer for plating. The first bonding metal portion 51 includes the first metal portion 51a located in the first connection hole 32 and the second metal portion 51b located on the second portion 61b of the first conductive film 61 via the second conductive film 71. The first bonding metal portion 51 is in contact with the second conductive film 71 in the first connection hole 32 and on the surface 33a of the first insulating layer 33.

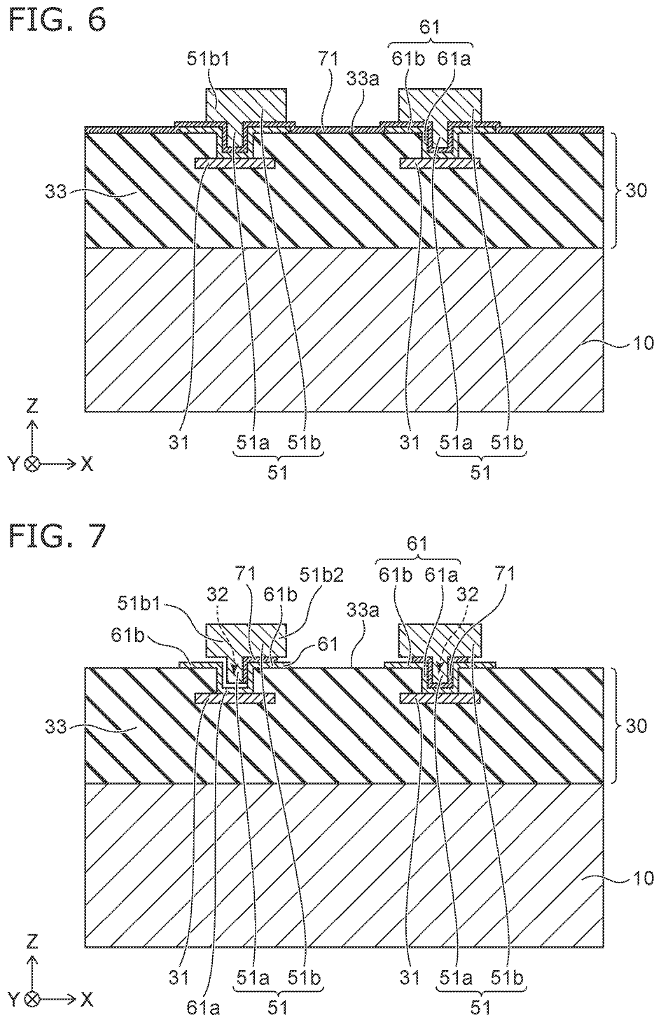

After the first bonding metal portion 51 is formed, the resist mask 91 is removed. By the removal of the resist mask 91, as shown in FIG. 6, a portion of the second conductive film 71 not covered with the first bonding metal portion 51 is exposed from the first bonding metal portion 51. In this state, an exposed portion of the second conductive film 71 is removed by a wet etching method. Since the first bonding metal portion 51 is made of a material different from the material of the second conductive film 71, the first bonding metal portion 51 functions as a mask during the wet etching.

As shown in FIG. 7, the second conductive film 71 remains under the first bonding metal portion 51, and the second conductive film 71 on the surface 33a of the first insulating layer 33 is removed. At this time, since the first conductive film 61 is made of a material different from the material of the second conductive film 71, the first conductive film 61 has resistance to the wet etching. Accordingly, the first conductive film 61 in contact with the first interconnection layer 31 can reliably remain in the first connection hole 32.

The resist mask 91 shown in FIG. 5 described above is formed on the entire surface of the second conductive film 71 and then patterned by exposure and development processing to form a plurality of openings 91a in the resist mask 91. The opening 91a is located on the first connection hole 32 and the second portion 61b of the first conductive film 61. At this time, a positional deviation of the opening 91a may occur. In FIG. 5, an opening 91a1 on a right side shows a state where no positional deviation occurs, and an opening 91a2 on a left side shows a state where a center position of the opening 91a2 is deviated to the right side as compared with the opening 91a1.

When the positional deviation occurs in the opening 91a2, as shown in FIG. 6, for example, the portion 51b1 whose width in the second direction X is reduced is formed in the second metal portion 51b of the first bonding metal portion 51 formed in the opening 91a2. In the wet etching, the etching of the second conductive film 71 under the portion 51b1 proceeds fast, and the second conductive film 71 is likely to disappear. When the second conductive film 71 under the portion 51b1 disappears, a gap is formed between the portion 51b1 and the second portion 61b of the first conductive film 61, and the etchant enters the first connection hole 32 through the gap. Accordingly, as shown in FIG. 7, a part of the second conductive film 71 in the first connection hole 32 may disappear.

According to the embodiment, by previously forming the first conductive film 61 in contact with the first interconnection layer 31 in the first connection hole 32 with a material different from that of the second conductive film 71, the first conductive film 61 in contact with the first interconnection layer 31 can reliably remain in the first connection hole 32 even after the etching process of the second conductive film 71. When the opening 91a2 of the resist mask 91 is deviated to the right side, in the second metal portion 51b of the first bonding metal portion 51, a width (a width in the second direction X) of the other portion 51b2 extending to the right side opposite to the portion 51b1 is larger than the width (the width in the second direction X) of the portion 51b1. Therefore, the second conductive film 71 can remain between the other portion 51b2 and the second portion 61b of the first conductive film 61. Accordingly, the etchant does not enter the first connection hole 32 from the other portion 51b2 side, and the second conductive film 71 can remain between the first metal portion 51a of the first bonding metal portion 51 and the first portion 61a of the first conductive film 61 on a side surface of the first connection hole 32 on the right side. Accordingly, even when the positional deviation between the first bonding metal portion 51 and the first connection hole 32 occurs, the first interconnection layer 31 and the first bonding metal portion 51 can be electrically connected via the first conductive film 61 and the second conductive film 71 on a side in a direction to which the position is deviated (the right side in this example).

The second chip 200 can also be formed by the same process as the first chip 100 described above. In the second chip 200, the third conductive film 62 is also made of a material different from the material of the fourth conductive film 72 and the material of the bonding metal portion 50. For example, the bonding metal portion 50 mainly contains gold, the third conductive film 62 mainly contains titanium nitride, and the fourth conductive film 72 mainly contains palladium or titanium. Accordingly, in the second chip 200, the third conductive film 62 in contact with the second interconnection layer 41 can also reliably remain in the second connection hole 42 even after an etching process of the fourth conductive film 72. Accordingly, the second interconnection layer 41 can be electrically connected to the bonding metal portion 50 via the third conductive film 62 and the fourth conductive film 72.

After the first chip 100 and the second chip 200 are formed, the first bonding metal portion 51 of the first chip 100 and the second bonding metal portion 52 of the second chip 200 face each other and are brought into contact with each other. Thereafter, heat and a force are applied to diffuse metals (in the example, gold) of the first bonding metal portions 51 and the second bonding metal portions 52, and the first bonding metal portions 51 and the second bonding metal portions 52 are bonded.

As shown in FIG. 7 described above, a gap may be formed between the portion 51b1 of the first bonding metal portion 51 and the second portion 61b of the first conductive film 61. However, as shown in FIG. 1, the portion 51b1 of the first bonding metal portion 51 is in contact with the second portion 61b of the first conductive film 61 and the gap is closed due to a pressing force during bonding of the first chip 100 and the second chip 200.

Due to the pressing force during the bonding of the first chip 100 and the second chip 200, the stress of the first conductive film 61 itself formed in the first connection hole 32, the thermal stress in the subsequent process, or the like, it is considered that cracks may occur particularly in a portion of the first conductive film 61 located at a corner of the bottom surface of the first connection hole 32. As described above, even when the gap is formed between the portion 51b1 of the first bonding metal portion 51 and the second portion 61b of the first conductive film 61, the gap is closed when the first chip 100 and the second chip 200 are bonded. Therefore, it is possible to prevent abnormal oxidation of the first interconnection layer 31 through cracks formed in the first conductive film 61 by heating during the bonding of the first chip 100 and the second chip 200.

### Second Embodiment

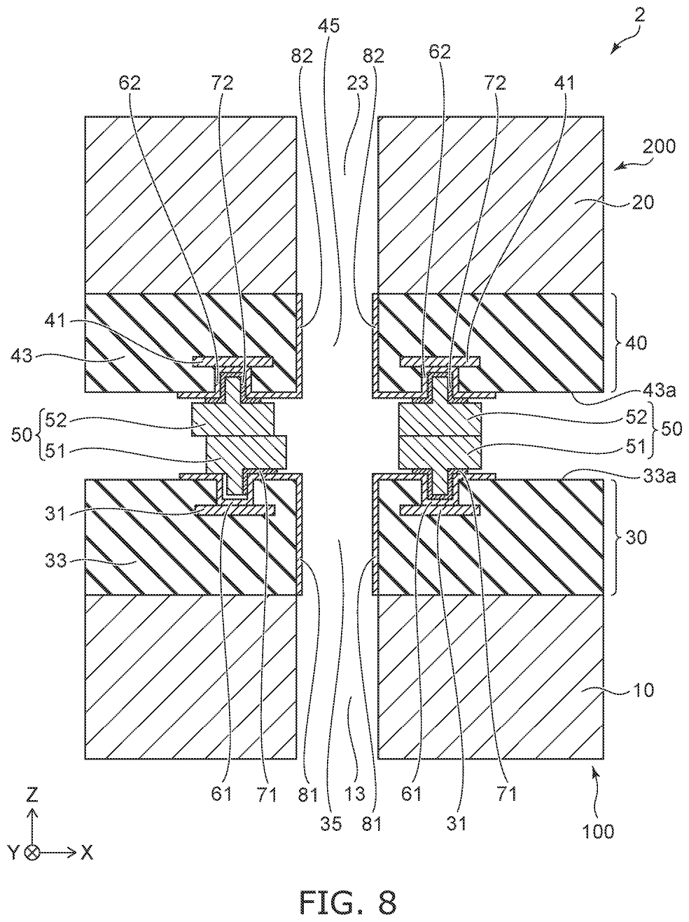

FIG. 8 is a schematic cross-sectional view of a bonding-type interconnection member 2 according to a second embodiment.

In the bonding-type interconnection member 2 according to the second embodiment, the first substrate 10 has a first through-hole 13, and the first interconnection portion 30 has a first interconnection portion through-hole 35. The first through-hole 13 and the first interconnection portion through-hole 35 extend in the first direction Z and are continuous with each other in the first direction Z. The second substrate 20 has a second through-hole 23, and the second interconnection portion 40 has a second interconnection portion through-hole 45. The second through-hole 23 and the second interconnection portion through-hole 45 extend in the first direction Z and are continuous with the first interconnection portion through-hole 35 and the first through-hole 13 in the first direction Z.

For example, a charged particle beam passes through the second through-hole 23, the second interconnection portion through-hole 45, the first interconnection portion through-hole 35, and the first through-hole 13. By bonding the two chips (the first chip 100 and the second chip 200) each having the through-holes, the bonding-type interconnection member 2 having deep through-holes, which is difficult to be formed in a single chip, can be implemented.

The bonding-type interconnection member 2 further includes fifth conductive films 81 provided on side surfaces of the first interconnection portion through-hole 35 and sixth conductive films 82 provided on side surfaces of the second interconnection portion through-hole 45.

The side surfaces of the first interconnection portion through-hole 35 are covered with the fifth conductive films 81, and the first insulating layer 33 of the first interconnection portion 30 is not exposed on the side surfaces of the first interconnection portion through-hole 35. The side surfaces of the second interconnection portion through-hole 45 are covered with the sixth conductive films 82, and the second insulating layer 43 of the second interconnection portion 40 is not exposed on the side surfaces of the second interconnection portion through-hole 45. Accordingly, under a usage environment, during preparation for usage, or during storage of the bonding-type interconnection member 2, moisture absorption to side surfaces of the first insulating layer 33 and side surfaces of the second insulating layer 43 can be prevented, and oxidation of the first interconnection layers 31 and the second interconnection layers 41 can be prevented. As a result, reliability of the bonding-type interconnection member 2 can be improved.

Charging of the side surfaces of the first insulating layer 33 and the side surfaces of the second insulating layer 43 can be prevented, and abnormal deflection of the charged particle beam can be prevented by the fifth conductive films 81 and the sixth conductive films 82.

When the first conductive film 61 is formed, the fifth conductive film 81 can be formed continuously with the first conductive film 61 using the same material as that of the first conductive film 61. When the third conductive film 62 is formed, the sixth conductive film 82 can be formed continuously with the third conductive film 62 using the same material as that of the third conductive film 62.

### Third Embodiment

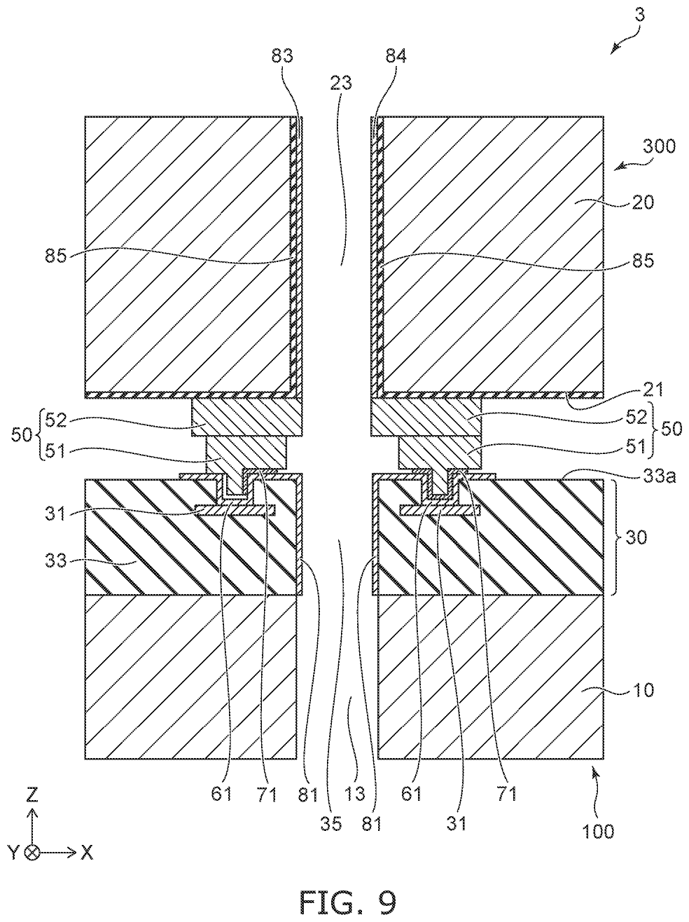

FIG. 9 is a schematic cross-sectional view of a bonding-type interconnection member 3 according to a third embodiment.

The first chip 100 and a second chip 300 are bonded via the bonding metal portions 50. The second chip 300 includes the second substrate 20. An interconnection portion is stacked only on the first substrate 10 of the first chip 100, and is not stacked on the second substrate 20 of the second chip 300. The second substrate 20 has the second through-hole 23 continuous with the first interconnection portion through-hole 35 and the first through-hole 13. The second bonding metal portions 52 are provided on the third surface 21 of the second substrate 20.

A first electrode film 83 and a second electrode film 84 are provided on side surfaces of the second through-hole 23 of the second substrate 20. The first electrode film 83 and the second electrode film 84 face each other and are spaced apart from each other in the second direction X, and are not connected in the second through-hole 23.

Lower end portions of the first electrode film 83 and the second electrode film 84 are connected to the second bonding metal portions 52. Each of the first electrode film 83 and the second electrode film 84 is electrically connected to the first interconnection layer 31 via the bonding metal portion 50, the second conductive film 71, and the first conductive film 61. The first interconnection layer 31 electrically connected to the first electrode film 83 and the first interconnection layer 31 electrically connected to the second electrode film 84 are not electrically connected, and different potentials can be applied to the first electrode film 83 and the second electrode film 84. Accordingly, a charged particle beam passing through the second through-hole 23 can be deflected.

For example, when the second substrate 20 has conductivity such as a silicon substrate, insulating films 85 are provided between the first electrode film 83 and the second substrate 20 and between the second electrode film 84 and the second substrate 20. When the second substrate 20 is an insulating substrate, the first electrode film 83 and the second electrode film 84 may be directly formed on the second substrate 20.

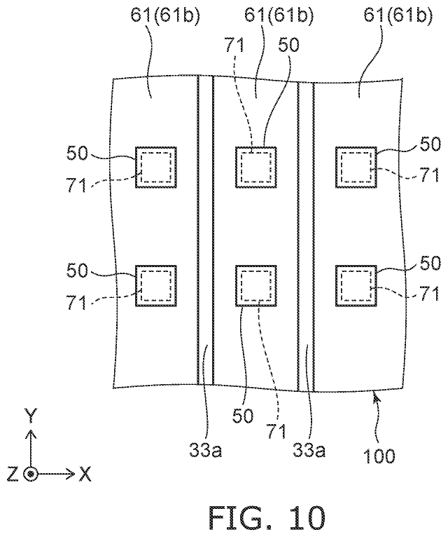

FIG. 10 is a schematic plan view showing an arrangement example of the surfaces 33a of the first insulating layers 33 and the bonding metal portions 50 in the first chip 100.

For example, the plurality of bonding metal portions 50 are arranged in the second direction X and the third direction Y. A plurality of the second conductive films 71 are separated from each other and provided under the plurality of bonding metal portions 50.

The first conductive films 61 electrically connect the plurality of bonding metal portions 50 to each other via the second conductive films 71. In the example shown in FIG. 10, the first conductive films 61 are continuously formed between the adjacent bonding metal portions 50 in the third direction Y, and electrically connect the adjacent bonding metal portions 50 in the third direction Y. Further, the first conductive films 61 may be continuously formed between the adjacent bonding metal portions 50 in the second direction X, and electrically connect the adjacent bonding metal portions 50 in the second direction X.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A bonding-type interconnection member, comprising:
a first substrate;
a first interconnection portion stacked on the first substrate and including a first insulating layer, a first interconnection layer provided in the first insulating layer, and a first connection hole reaching the first interconnection layer from a surface of the first insulating layer;
a second substrate facing the first interconnection portion in a first direction;
a bonding metal portion provided between the first connection hole and the second substrate in the first direction;
a first conductive film provided in the first connection hole and in contact with the first interconnection layer on a bottom surface of the first connection hole; and
a second conductive film provided between the first conductive film and the bonding metal portion, and in contact with the first conductive film and the bonding metal portion,
the first conductive film being made of a material different from a material of the second conductive film and a material of the bonding metal portion.

2. The member according to claim 1, wherein
the first conductive film includes a first portion located in the first connection hole and a second portion located on the surface of the first insulating layer,
the bonding metal portion includes a first metal portion located in the first connection hole and a second metal portion facing the second portion of the first conductive film, and
the second conductive film is in contact with the first conductive film and the bonding metal portion between the second metal portion and the second portion.

3. The member according to claim 2, wherein
the second conductive film is in contact with the first conductive film and the bonding metal portion between a side surface of the first metal portion and the first portion.

4. The member according to claim 2, wherein
the bonding metal portion has a portion where the second metal portion and the second portion are in direct contact with each other.

5. The member according to claim 1, wherein
a plurality of the bonding metal portions are provided side by side in a direction orthogonal to the first direction,
a plurality of the second conductive films are separated from each other and respectively provided under the plurality of bonding metal portions, and
the first conductive film electrically connects the plurality of bonding metal portions to each other via the second conductive films.

6. The member according to claim 1, further comprising:
a second interconnection portion stacked on the second substrate, located between the first interconnection portion and the second substrate in the first direction, and including a second insulating layer, a second interconnection layer provided in the second insulating layer, and a second connection hole reaching the second interconnection layer from a surface of the second insulating layer;
a third conductive film provided in the second connection hole and in contact with the second interconnection layer on a bottom surface of the second connection hole; and
a fourth conductive film provided between the third conductive film and the bonding metal portion, and in contact with the third conductive film and the bonding metal portion, wherein
the third conductive film is made of a material different from a material of the fourth conductive film and the material of the bonding metal portion.

7. The member according to claim 1, wherein
the first substrate has a first through-hole,
the first interconnection portion has a first interconnection portion through-hole continuous with the first through-hole in the first direction, and
the second substrate has a second through-hole continuous with the first interconnection portion through-hole and the first through-hole in the first direction.

8. The member according to claim 7, further comprising:
a fifth conductive film provided on a side surface of the first interconnection portion through-hole.

9. The member according to claim 7, further comprising:
an electrode film provided on a side surface of the second through-hole and electrically connected to the first interconnection layer via the first conductive film, the second conductive film, and the bonding metal portion.

10. The member according to claim 1, wherein
the bonding metal portion mainly contains gold,
the first conductive film mainly contains titanium nitride, and
the second conductive film mainly contains palladium, titanium, or a stacked film of a palladium film and a titanium film.
